(19) United States
(12) Patent Application Publication
(10) Pub. No.: US 2007/0042566 A1
(43) Pub. Date: Feb. 22, 2007

(54) STRAINED SILICON ON INSULATOR (SSOI) STRUCTURE WITH IMPROVED CRYSTALLINITY IN THE STRAINED SILICON LAYER

(75) Inventors: Michael R. Seacrist, St. Peters, MO (US); Lu Fei, St. Peters, MO (US)

Correspondence Address: SENNIGER POWERS, ONE METROPOLITAN SQUARE, 16TH FLOOR, ST LOUIS, MO, 63102, US

(73) Assignee: MEMC ELECTRONIC MATERIALS, INC., St. Peters, MO (US)

(21) Appl. No.: 11/461,653

(22) Filed: Aug. 1, 2006

Related U.S. Application Data
(60) Provisional application No. 60/705,039, filed on Aug. 3, 2005.

(51) Int. Cl. H01L 21/30; H01L 33/00

(52) U.S. Cl. 438/458; 438/508

(57) ABSTRACT

This invention generally relates to strained silicon on insulator (SSOI) structure, and to a process for making the same. The process includes a high temperature thermal anneal of a SSOI structure to improve the crystallinity of the strained silicon layer, while maintaining the strain present therein.

### REFERENCE TO RELATED APPLICATIONS

This application claims priority from U.S. provisional application Ser. No. 60/705,039 filed on Aug. 3, 2005, the entire disclosure of which is incorporated herein by reference.

### FIELD OF THE INVENTION

The present invention relates generally to a strained silicon on insulator (SSOI) structure. More particularly, the present invention is directed to a SSOI structure wherein the strained silicon layer has improved crystallinity. The present invention is further directed to a method for making such a structure.

### BACKGROUND OF THE INVENTION

Silicon on insulator (SOI) structures generally comprise a handle wafer, a semiconductor device layer, and a dielectric insulating layer between the handle wafer and the device layer. By insulating the device layer from the handle wafer of the SOI structure, the device layer yields reduced leakage currents and lower capacitance. Strained silicon on insulator (SSOI) structures for semiconductor devices combine these benefits of SOI technology with strained silicon technology, with the strained silicon layer providing enhanced carrier mobility.

The strained silicon on insulator structure may be fabricated or manufactured in a number of ways. For example, in one approach, a relaxed silicon-germanium (SiGe) layer is formed on an insulator by one of several techniques known in the art, such as: (i) separation by implantation of oxygen (known as “SIMOX”, see, e.g., U.S. Pat. No. 5,436,175); (ii) wafer bonding followed by back etching; (iii) wafer bonding followed by hydrogen exfoliation layer transfer; or (iv) recrystallization of amorphous material. This is followed by the epitaxial deposition or growth of a strained silicon layer on the SiGe layer. The relaxed SiGe-on-insulator layer serves as the template for inducing strain in the Si layer, the induced strain typically being greater than approximately 10⁻³.

Such a structure has limitations, however. For example, it is not conducive to the production of fully-depleted strained semiconductor on insulator devices in which the layer over the insulating material must be thin enough (e.g., less than 300 angstroms) to allow for full depletion of the layer during device operation. Additionally, the relaxed SiGe layer adds to the total thickness of the layer over the insulating material, and thus makes it difficult to achieve the thicknesses required for fully depleted silicon on insulator device fabrication.

Such problems may be alleviated if the strained SOI structure has the strained Si layer disposed directly on the insulating material. (See, e.g., published U.S. Patent Application No. 2004/0005740). This may be achieved, for example, by utilizing both wafer bonding and separation by implantation techniques. Specifically, a relaxed layer of, for example, SiGe may be formed on the surface of one wafer or substrate. A strained silicon layer may then be formed by, for example, epitaxial deposition, on the surface of the relaxed layer. Hydrogen ions may then be implanted into the relaxed layer to define a cleave or separation plane therein according to any technique generally known in the art, such as for example the process disclosed in U.S. Pat. No. 6,790,747. The resulting structure may then be bonded to a second wafer or substrate, having a dieletric insulating layer on the surface thereof, with the surface of the strained layer being bound to the dieletric layer surface. Once bound, the resulting structure may then be separated along the cleave or separation plane, to yield a strained silicon on insulator structure.

Regardless of the specific process by which the SSOI structure was prepared, typical processes employing wafer bonding utilize a high temperature anneal. However, this high temperature anneal is not entirely compatible with strained materials because it may disrupt the beneficial properties of the strained layer. For example, the high temperature anneal may result in the relaxation of the strained Si layer, or it may cause Ge to diffuse to the strained Si layer from the top SiGe layer by diffusion. Conversely, if a thermal anneal is either omitted or performed at temperatures below about 950° C., the properties of the SSOI structure are also limited in that, for example, the quality of the crystalline structure of the strained Si layer may be less than desired.

### SUMMARY OF THE INVENTION

Briefly, therefore, the present invention is directed to a process for preparing a strained silicon on insulator structure comprising a handle wafer, a strained silicon layer, and a dielectric layer between the handle wafer and the strained silicon layer, the process comprising annealing the strained silicon on insulator structure at a temperature and for a duration such that the strained silicon layer has a crystallinity which differs from the crystallinity of the handle wafer by less than about 10%.

The process of this invention further comprises forming a relaxed silicon-comprising layer on a surface of a donor wafer; forming a strained silicon layer on the relaxed silicon-comprising layer; forming the dielectric layer on a surface of the handle wafer; bonding the strained silicon layer of the donor wafer to the dielectric layer of the handle wafer to form a bonded wafer, wherein a bond interface is formed between the strained silicon layer and the dielectric layer; separating the bonded wafer along a separation plane within the relaxed silicon-comprising layer, such that the strained silicon layer on said handle wafer has a residual relaxed silicon-comprising layer on the surface thereof; and, etching the residual relaxed silicon-comprising layer to substantially remove said layer from the strained silicon layer.

In another aspect, the current invention is directed to a strained silicon on insulator structure comprising a handle wafer, a strained silicon layer, and an oxide layer between the handle wafer and the strained layer, said strained layer having a crystallinity which differs from the crystallinity of the handle wafer by less than about 10%.

Other objects and features of this invention will be in part apparent and in part pointed out hereinafter.

### BRIEF DESCRIPTION OF THE DRAWINGS

FIG. 1A is a cross-sectional, schematic drawing of a donor wafer 12 having on a surface thereof a relaxed silicon-comprising layer 13 and a strained silicon layer 14. The dashed line 17 in the relaxed silicon-comprising layer 13 represents a separation or cleave plane, present therein.

FIG. 1B is a cross-sectional, schematic drawing of a handle wafer 16 comprising a dielectric layer 15 disposed on a surface thereof, prior to bonding with the wafer of 1A.

FIG. 2 is a cross-sectional, schematic drawing of a bonded structure 20, resulting from contacting the surface of the strained silicon layer 14 of the donor wafer (illustrated in FIG. 1A) to the surface of the dielectric layer 15 of the handle wafer (illustrated in FIG. 1B).

FIG. 3 is a cross-sectional, schematic drawing which illustrates separation of the bonded structure 20 along the separation or cleave plane 17 in the relaxed silicon-comprising layer 13, and thus the transfer of the strained silicon layer 14, with a residual portion of the relaxed silicon-comprising layer 33 that may optionally be present thereon, to the handle wafer 16/dielectric layer 15.

FIG. 4 is a cross-sectional, schematic drawing of the strained silicon on insulator structure of the present invention 40.

Corresponding reference characters indicate corresponding parts throughout the drawings.

### DETAILED DESCRIPTION OF THE PREFERRED EMBODIMENTS

In accordance with the present invention, an improved process for making a strained semiconductor on insulator structure having a strained semiconductor layer with improved crystallinity and capable of improved electrical performance has been devised. More specifically, it has been discovered that a high temperature thermal anneal is a useful means of improving the crystallinity of the strained semiconductor layer without relaxation thereof. In accord with the invention, the semiconductor material may be any material generally known in the art suitable for semiconductor applications, such as a silicon-comprising material. For exemplary purposes herein, the semiconductor material is silicon being utilized in an SSOI structure. It should also be appreciated that the improved features of this invention may be desirable in other semiconductor applications, such as semiconductor layer stacks. Such layer stacks include, e.g., SSi/PNO/polysilicon/SiO₂ (BOX) or SSi/HfO₂/TaSiN/polysilicon/SiO₂ (BOX) stacks, where PNO refers to “plasma nitrided gate oxide” and BOX refers to “buried oxide.”

It is to be noted that the high temperature thermal anneal of the present invention is readily integrated into known processes of making SSOI structures. Such processes include, for example, the aforementioned process of U.S. Pat. No. 6,790,747, as well as the wafer bonding and layer transfer techniques described in U.S. Patent Application Publication Nos. 2004/0005740 and 2004/0031979, the entire contents of which are incorporated herein by reference for all purposes. Accordingly, essentially any of the techniques generally known for preparing a SSOI structure may be employed in accordance with the present invention. Preferably, the process of the present invention utilizes wafer bonding and layer transfer techniques. The present invention will therefore be set forth in greater detail below in the context of these techniques. It is to be understood, however, that this is for purposes of illustration and should not be viewed in a limiting sense. It is to be further understood that, in the practice of the present invention, these techniques may be suitably carried out using a variety of apparatus and process conditions well-known in the art and, in some instances, may be omitted or combined with other techniques and conditions without departing from the scope of the present invention.

1. Formation of the Strained Silicon Layer

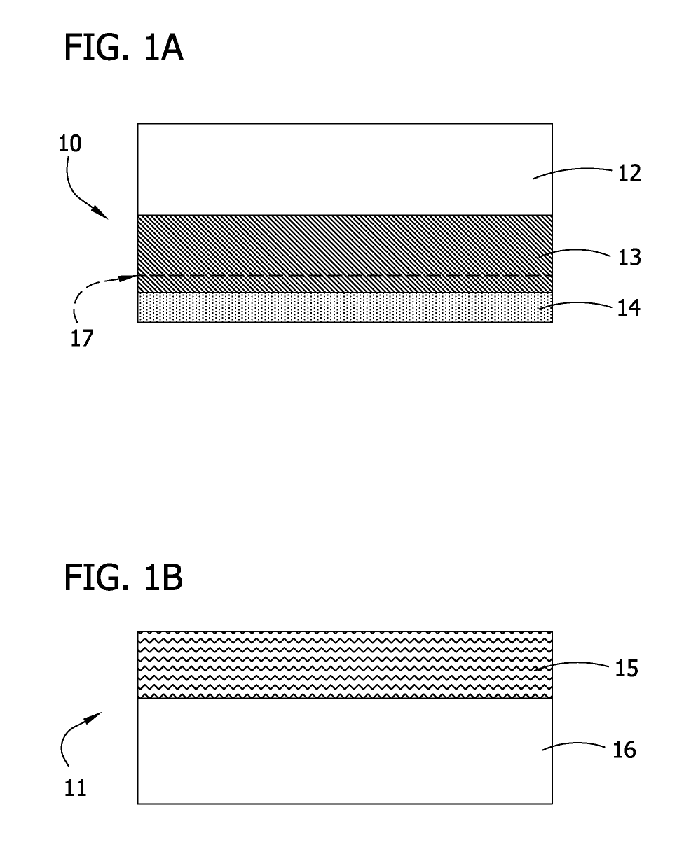

While many techniques may be used to form the SSOI structure, for purposes of illustration of some of the preferred embodiments of the present invention, a process for preparing a SSOI structure by means of wafer bonding and layer transfer techniques will be described herein in greater detail, with reference to FIGS. 1-4. Generally speaking, these techniques comprise the preparation of two separate structures, bonding them together along a bond interface, and then delaminating them along a separation plane that is different from the bond interface and that has been formed via an implantation technique. Each structure comprises a substrate or supporting wafer, which may be made of quartz or sapphire, but more commonly comprises a semiconductor material, such as silicon (e.g., single crystal silicon, prepared for example in accordance with the Czochralski method), germanium, or silicon-germanium (SiGe). In one preferred embodiment, the substrates comprise a single crystal silicon wafer, the wafer having a diameter of at least about 150 mm, 200 mm, 300 mm, or more.

One substrate will be referred to hereinafter as the “handle wafer.” The handle wafer has a dielectric layer directly disposed on a surface thereof, and serves as the substrate for the final SSOI structure. The other substrate will be referred to hereinafter as the “donor wafer.” The donor wafer has a relaxed silicon-comprising layer that is directly disposed on a surface thereof and, in one embodiment, serves as the substrate upon which the strained silicon layer is formed prior to a wafer bonding step. In one alternative embodiment, an amount of dielectric layer material is disposed on the strained silicon layer prior to the wafer bonding step.

A. Donor Wafer Structure

Referring now to FIG. 1A, the donor wafer structure 10 comprises a donor wafer or substrate 12, a relaxed silicon-comprising layer 13 on a surface thereof having a lattice constant different than that of a relaxed silicon lattice, and a strained silicon layer 14 on a surface of the relaxed silicon-comprising layer. In one preferred embodiment, the silicon-comprising layer is SiGe. The specific composition of the relaxed SiGe layer may vary according to the desired level of lattice strain to be induced in the strained silicon layer. Typically, the SiGe layer comprises at least about 10% Ge, and in some instances may comprise about 15%, about 20%, about 25%, about 35%, about 50% or more (e.g., 60%, 70%, 80%, 90% or more). In one preferred embodiment, however, the SiGe layer has a Ge concentration in the range of at least about 10% to less than about 50%, or from at least about 15% to less than about 35%, with a concentration of about 20% Ge being preferred.

Essentially any technique generally known in the art may be used to form the relaxed silicon-comprising (e.g., SiGe) layer, such as one of the known epitaxial deposition techniques. Generally speaking, the thickness of the relaxed layer is sufficient to permit substantially full plastic relaxation of the SiGe crystal lattice. Typically, the relaxed layer has a substantially uniform thickness, the average thickness thereof being at least about 0.1 microns, such as at least about 0.5 microns, at least about 1.0 micron, and even at least about 2.0 microns. Alternatively, it may be desirable to express thickness in terms of a range. For example, the average thickness may typically be in the range of from about 0.1 microns to about 2.0 microns, such as from about 0.5 micron to about 1.0 micron. In one preferred embodiment, the SiGe layer has an average thickness of about 2.0 microns. It is to be noted that the ranges and minimum thickness values set forth above are not narrowly critical to the invention, so long as the thickness is sufficient to permit substantially full plastic relaxation of the crystal lattice of the relaxed layer.

A strained layer 14 of, for example, silicon is formed or deposited on the relaxed (e.g., SiGe) layer 13, where the strain results from the difference in lattice constants between, for example, the strained Si layer and the relaxed SiGe layer. Such strain consequently alters the crystallinity of the silicon of the strained layer.

Like the relaxed layer, essentially any technique generally known in the art may be used to form or deposit the strained layer on the relaxed layer, provided strain is present in the layer after deposition thereof. In one preferred embodiment, one of the known epitaxial deposition techniques (e.g., atmospheric-pressure chemical vapor phase deposition (APCVD); low- or reduced-pressure CVD (LPCVD); ultra-high-vacuum CVD (UHVCVD); molecular beam epitaxy (MBE); or, atomic layer deposition (ALD)), is used wherein by chemical vapor deposition, for example, silane, disilane, or trislane are deposited. The epitaxial growth system may comprise a single-wafer or a multiple-wafer batch reactor. The strained layer may be formed at a relatively low temperature, e.g., less than 700° C., possibly in order promote a defined interface between the strained layer and the relaxed layer. A defined interface may enhance the subsequent separation or removal of the strained layer from the relaxed layer. In an embodiment in which the strained layer contains substantially 100% Si, this layer may be formed in a dedicated chamber of a deposition tool that is not exposed to, for example, a Ge source gas. By doing so, cross-contamination is avoided and a higher quality interface is promoted between the strained layer and relaxed layer. Additionally, the strained layer may be formed from an isotopically pure silicon precursor, which has better thermal conductivity than conventional Si. Higher thermal conductivity may help dissipate heat from devices subsequently formed on the strained layer, thereby maintaining the enhanced carrier mobilities provided by the strained layer.

Generally speaking, the strained layer 14 is grown to a substantially uniform thickness which is sufficient for subsequent device fabrication, but not thick enough for the crystal lattice at the exposed silicon surface to undergo significant plastic relaxation. Typically, therefore, the strained layer is grown to an average thickness of at least about 1 nm, such as between about 1 nm and about 100 nm, preferably between about 10 nm and about 80 nm, and more preferably between about 15 nm and about 40 nm. In one preferred embodiment, the average thickness of the silicon layer is about 20 nm.

Referring again to FIG. 1A, ions, such as hydrogen ions, may be implanted into the relaxed layer 13 at a substantially uniform depth. If the ions are implanted into the relaxed layer before the strained layer 14 is formed, the ions are implanted through the surface of the relaxed layer 13 on which the strained layer is subsequently formed. If the ions are implanted into the relaxed layer after the strained layer 14 is formed, the ions are implanted through the strained layer 14 and into the relaxed layer 13. This ion implantation defines a separation or cleave plane 17 in the relaxed layer. Preferably, ions are implanted to an average depth that is sufficient to ensure a satisfactory transfer of the strained layer upon a subsequent thermal treatment, while limiting the amount of relaxed layer transferred therewith as much as possible. Typically, as further detailed herein below, the ions are implanted at least about 20, 30, 40 or even 50 nm, or more into the relaxed layer. For example, in some instances the ions are implanted at least about 65 nm, 75 nm, 85 nm, 100 nm, 150 nm, 200 nm or more into the relaxed layer. Ion implantation may be achieved using means known in the art. For example, this implantation may be achieved in a manner according to the process of U.S. Pat. No. 6,790,747. Implantation parameters may include, for example, implantation of hydrogen ions (H⁺) to a dose from about 1 to about 5×10¹⁶ ions/cm² at an energy of, for example, about 20 to about 100 keV (e.g., H⁺ may be implanted at an energy of 28 keV and a dose of 2.6×10¹⁶ ions/cm² through the strained layer and into the relaxed layer).

In this regard it is to be noted that, in an alternative embodiment, other implanted species may be used, such as for example H₂⁺ or He⁺, with the dose and energy being adjusted accordingly.

It is to be further noted that when implantation is performed prior to formation of the strained layer, the subsequent growth or deposition of the strained layer on the relaxed layer is preferably performed at a temperature low enough to prevent premature separation or cleaving along plane 17 in the relaxed layer (i.e., prior to the wafer bonding process step). The separation or cleaving temperature is a complex function of the implanted species, implanted dose, and implanted material. For example, it has been suggested that premature separation or cleaving may be avoided in some instances by maintaining a deposition or growth temperature below about 500° C.

B. Handle Wafer Structure

Referring now to FIG. 1B, the handle wafer structure 11 comprises a handle wafer or substrate 16 having a dielectric layer 15 on a surface thereof, which functions as an insulating layer in the final SSOI structure. The dielectric layer may be of any electrically insulating material suitable for use in an SSOI structure, such as for example a material comprising SiO₂, Si₃N₄, aluminum oxide, or magnesium oxide. In one preferred embodiment, the dielectric layer is SiO₂. However, it is to be noted that, in some instances, it may alternatively be preferred to use a material for the dielectric layer that has a melting point higher than the melting point of pure SiO₂, i.e., approximately 1700° C. Examples of such materials are silicon nitride (Si₃N₄), aluminum oxide, magnesium oxide, etc. Without being bound by a particular theory, it is generally believed that using a dielectric layer with a higher melting point may help prevent possible relaxation of the transferred strained layer, during subsequent processing, due to softening of the underlying dielectric layer at temperatures typically used during device fabrication, i.e., approximately 1000-1200° C.

The dielectric layer may be applied according to any known technique in the art, such as thermal oxidation, wet oxidation, or thermal nitridation. Generally speaking, the dielectric layer is grown to a substantially uniform thickness sufficient to provide the desired insulating properties in the final SSOI structure. Typically, the dielectric layer has an average thickness of at least about 10 nm, such as about 50 nm, about 100 nm, about 125 nm, about 150 nm, about 175 nm, or about 200 nm. Alternatively, the average thickness of the dielectric layer may be expressed as a range, such as between about 10 nm to about 200 nm, preferably between about 50 nm to about 175 nm, and even more preferably between about 100 nm to about 150 nm. In one preferred embodiment, the dielectric layer has a thickness of about 145 nm.

C. Wafer Bonding and Transfer of the Strained Layer

Once the donor wafer structure 10 and handle wafer structure 11 have been prepared, forming the final SSOI structure comprises transferring the strained silicon layer of the donor wafer structure onto the dielectric layer of the handle wafer structure. Generally speaking, this transfer is achieved by contacting the surface of the dielectric layer 15 to the surface of the strained layer 14 in order to form a single, bonded structure 20 with a bond interface 18 between the two surfaces, and then cleaving or separating the bonded structure along the separation or cleave plane 17 in the relaxed layer.

Prior to bonding, the surfaces of the strained silicon layer and/or the dielectric layer may optionally undergo cleaning, a brief etching, and/or planarization to prepare their surfaces for bonding, using techniques known in the art. Without being bound by a particular theory, it is generally believed that the quality of the surface of the strained silicon layer in the final SSOI structure is, in part, a function of the quality of the surface prior to bonding. Additionally, the quality of both surfaces prior to bonding will have a direct impact on the quality or strength of the resulting bond interface.

The roughness of the surface is one way by which the surface quality is quantitatively measured, with lower surface roughness values corresponding to a higher quality surface. Therefore, the strained layer and/or the dielectric layer may undergo processing to reduce the surface roughness. For example, in one embodiment, the surface roughness is less than about 0.5 nm root mean square (RMS). This lowered RMS value can be achieved prior to bonding by cleaning and/or planarization. Cleaning may be carried out according to a wet chemical cleaning procedure, such as a hydrophilic surface preparation process. One common hydrophilic surface preparation process is a RCA SC1 clean process, wherein the surfaces are contacted with a solution containing ammonium hydroxide, hydrogen peroxide, and water at a ratio of, for example, 1:4:20 at about 60° C. for about 10 minutes, followed by a deionized water rinse and spin dry. Planarization may be carried out using a chemical mechanical polishing (CMP) technique. Further, one or both of the surfaces may be subjected to a plasma activation to increase the resulting bond strength before, after, or instead of a wet cleaning process. The plasma environment may include, for example, oxygen, ammonia, argon, nitrogen, diboran, or phosphine. In one preferred embodiment, the plasma activation environment is selected from the group consisting of nitrogen, oxygen, and combinations thereof.

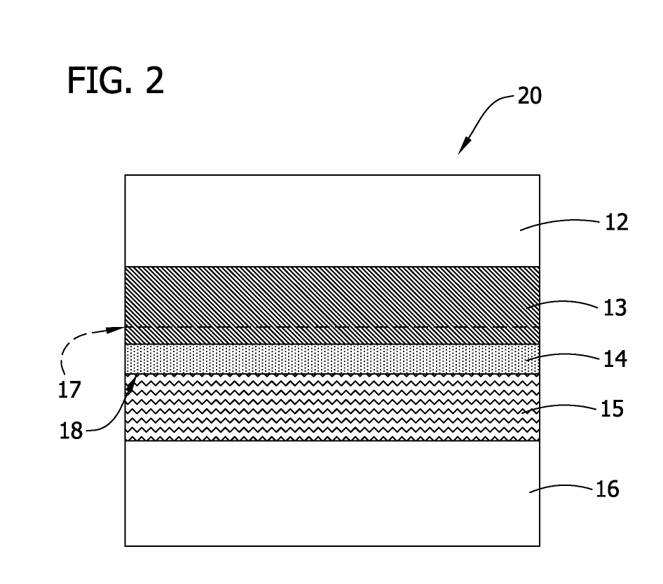

Referring now to FIG. 2, the donor wafer structure is bonded to the handle wafer by bringing the surfaces of the strained layer 14 and the dielectric layer 15 together to form a bond interface 18. Generally speaking, wafer bonding may be achieved using essentially any technique known in the art, provided the energy employed to achieve formation of the bond interface is sufficient to ensure the integrity of the bond interface is sustained during subsequent processing, such as layer transfer by cleaving or separation. Typically, however, wafer bonding is achieved by contacting the surface of the strained layer and the dielectric layer at room temperature, followed by heating at an elevated temperature for a period of time sufficient to produce a bond interface having a bond strength greater than about 500 mJ/m², about 750 mJ/m², about 1000 mJ/m², or more. To achieve such bond strength values, typically heating takes place at temperatures of at least about 200° C., 300° C., 400° C., or even 500° C. for a period of time of at least about 5 minutes, 30 minutes, 60 minutes, or even 300 minutes.

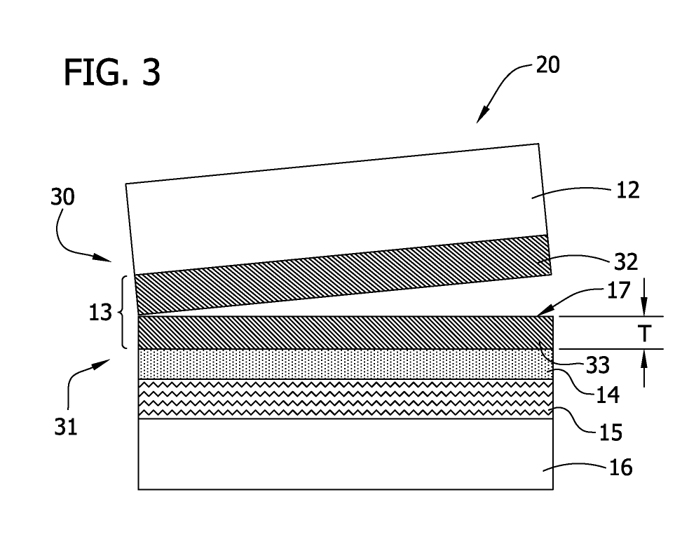

Referring now to FIG. 3, after the bond interface 18 has been formed, the resulting bonded structure 20 is subjected to conditions sufficient to induce a fracture along the separation or cleave plane 18 within the relaxed layer 13. Generally speaking, this fracture may be achieved using techniques known in the art, including, e.g., thermally-induced separation, mechanical separation, or a combination thereof. In one embodiment, annealing the bonded structure at an elevated temperature for a period of time can be employed to induce fracture. For example, the annealing temperature may be at least about 250° C., 350° C., 450° C., 550° C., 650° C., or even 750° C. Preferably, the temperature is between about 250° C. to about 750° C., and more preferably from about 350° C. to about 650° C. The anneal is performed over a time period of at least about 5 minutes, 30 minutes, 60 minutes, or even 300 minutes. Higher annealing temperatures will require shorter anneal times, and vice versa. The annealing step can be conducted in an ambient or inert atmosphere, e.g., argon or nitrogen.

Furthermore, another embodiment comprises inducing separation in the relaxed layer by mechanical force, either alone or in addition to the annealing process. The actual means of applying such a mechanical force is not critical to this invention; i.e., any known method of applying a mechanical force to induce separation in the relaxed layer may be employed, so long as substantial damage to the strained layer is avoided. In one preferred embodiment, mechanical force is used to induce separation in addition to an anneal of less than about 350° C.

Referring again to FIG. 3, two structures (30 and 31) are formed upon separation. If the separation of the bonded structure 20 occurs along the separation or cleave plane 17 in the relaxed layer 13, and the separation plane 17 does not coincide with the interface 18, but rather is present in the relaxed layer, a portion of the relaxed layer is part of both structures (i.e., a portion of the relaxed layer is transferred along with the strained layer). Structure 30 comprises the donor wafer 12 and some portion 32 of the relaxed layer 13. Structure 31 comprises the handle wafer 16, the dielectric layer 15, and the strained silicon layer 14 with a residual portion 33 of the relaxed layer 13 on the surface thereof.

When present, the residual relaxed layer 33 has a thickness (T) that is approximately equivalent to the depth at which ions were implanted into the relaxed layer. Accordingly, this thickness (T) is typically greater than about 20, 30, 40 or even 50 nm. For example, in some instances the residual layer may optionally be at least about 65 nm, 75 nm, 85 nm, 100 nm, 150 nm, 200 nm thick or more. Preferably, the thickness (T) is sufficient to avoid damage to the strained layer upon separation; for example, in one preferred embodiment, the residual layer is between about 80 nm to about 90 nm thick.

2. Finishing the Strained Silicon Surface after Layer Transfer

A. Removal of Residual Relaxed Layer

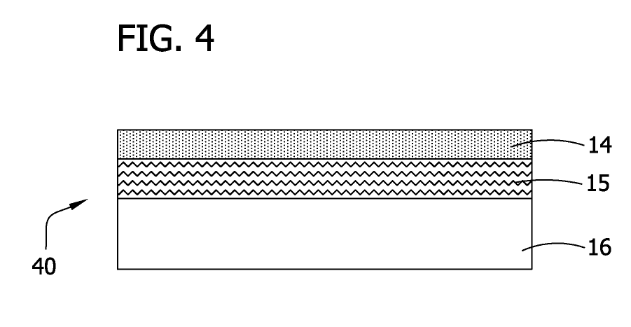

In accord with this invention and referring to FIGS. 3 and 4, after the strained silicon layer 14 has been transferred to the handle wafer 16 to form structure 31, structure 31 is subjected to additional processing to produce a strained silicon layer having desirable features for device fabrication thereon. For example, if a residual relaxed silicon-comprising layer 33 is present, structure 31 may be subjected to one or more processing steps in order to remove this residual layer. Although essentially any technique known in the art may be used, this residual layer is preferably removed via etching. In one preferred embodiment, substantially all of the residual relaxed layer is removed via a wet etching process using an etchant comprising NH₄OH, H₂O₂ and H₂O. This etchant is available commercially in various formulations and is commonly referred to as an “SC1” solution.

As shown in FIG. 4, the final SSOI structure 40 comprises a silicon handle wafer 16 and a strained silicon layer 14 with a dielectric layer 15 therebetween, the surface of the strained layer after etching preferably being substantially free of the relaxed layer 33. In this regard it is to be noted that, as used herein, “substantially removed” and/or “substantially free” refer to the essential absence of any detectable elements from the residual relaxed layer on the SSOI surface. For example, in one preferred embodiment, the strained silicon surface comprises no detectable Ge atoms, the detection limit thereof using means known in the art currently being about 1.0×10⁸ Ge atoms/cm².

Accordingly, the SSOI surface preferably comprises no detectable amount of any elements that were originally introduced to the strained layer to induce strain therein. For example, Ge is preferably removed to the fullest extent possible, as residual Ge may interfere with subsequent device fabrication or operation. Therefore, in accord with this invention, the strained silicon surface is substantially free of the relaxed layer after etching. However, in some instances the surface may have some detectable amount of, for example, Ge present therein. In such instances, the strained silicon surface preferably comprises less than about 1.0×10¹⁰ Ge atoms/cm², such as less than about 7.5×10⁹ Ge atoms/cm², less than about 5.0×10⁹ Ge atoms/cm², less than about 2.5×10⁹ Ge atoms/cm², or even less than about 1.0×10⁹ Ge atoms/cm².

The appropriate etching composition is selected according to various factors, including the precise composition of the residual relaxed layer and the selectivity of the etchant, wherein “selectivity” refers to the preferential rate at which the etchant removes the relaxed layer material in relation to the strained layer material. In one preferred embodiment, the selectivity of the etchant is evaluated with respect to the rate at which the relaxed SiGe layer is removed compared to the rate at which the strained silicon layer is removed. This ratio of SiGe:Si removal is at least in part dependent upon the concentration of Ge in the relaxed SiGe layer, as well as the etchant composition. Generally speaking, higher selectivity etchants are preferred so that the residual relaxed SiGe layer is removed quickly while retaining as much of the strained silicon layer as possible.

As previously noted, the concentration of Ge in the residual layer is at least about 10% Ge, and in some instances may be at least about 15%, about 20%, about 25%, about 35%, about 50% or more (e.g., 60%, 70%, 80%, 90% or more). In one preferred embodiment, however, the SiGe layer has a Ge concentration in the range of at least about 10% to less than about 50%, or from at least about 15% to less than about 35%, with a concentration of about 20% Ge being most preferred.

Typically, the etchant comprises NH₄OH, H₂O₂ and H₂O in a ratio sufficient to remove the residual relaxed SiGe layer from the handle wafer with a selectivity of SiGe:Si of at least about 3:1. Preferably, the etchant comprises NH₄OH, H₂O₂, and H₂O in a ratio sufficient to achieve a selectivity of at least about 3.5:1, more preferably at least about 4:1, still more preferably at least about 4.5:1, and even more preferably at least about 5:1 or more. In one preferred embodiment, a particularly preferred etchant comprises NH₄OH:H₂O₂:H₂O in a ratio of about 1:2:50.

Generally speaking, the duration of the etching process and the temperature at which the process takes place are sufficient to substantially remove the residual relaxed layer. The precise etching time depends on the thickness of the SiGe layer, which is in turn a function of the original ion implant energy. Typically, however, the handle wafer is exposed to the etchant for between about 1 minute to about 1000 minutes, such as between about 10 minutes to about 500 minutes, or about 20 minutes to about 200 minutes. Additionally, the handle wafer is typically etched at a temperature of between about 1° C. to about 100° C., such as between about 10° C. to about 90° C., and between about 50° C. to about 75° C., with longer etching times corresponding to lower temperatures and shorter etching times corresponding to higher temperatures. In one preferred embodiment, the etching takes place at about 65° C. for about 200 minutes.

During the etching process, agitation is typically applied to facilitate the removal of the residual relaxed SiGe layer, thereby enabling etching to be achieved over shorter durations. In one embodiment, megasonic agitation or treatment is employed at a power level typically ranging from about 5 to about 1500 watts. For example, the power of the megasonic etching may range from about 10 to about 1250 watts, from about 25 to about 1000 watts, from about 50 to about 750 watts, or from about 100 to about 500 watts.

B. Improving Crystallinity of the Strained Layer

After the optional removal of the residual relaxed layer (e.g., the residual SiGe layer), structure 31 undergoes subsequent processing to produce a strained silicon surface having desirable features for device fabrication thereon. Particularly, as detailed herein below, structure 31 is annealed under conditions sufficient to improve the crystallinity of the strained Si layer thereon, while limiting or preferably substantially avoiding relaxation of the strain layer.

Typically, the SSOI structure 31 is annealed at a temperature between about 950° C. to about 1200° C. For example, SSOI structure 31 may be annealed between about 1000° C. to about 1175° C., preferably between about 1025° C. to about 1150° C., and more preferably between about 1050° C. to about 1125° C. The duration of the anneal will vary according to the annealing temperature, with longer anneal times being used with lower temperatures and shorter times used at higher temperatures. Typically, the SSOI structure 31 is annealed for a duration between about 15 minutes to about 150 minutes, such as between about 30 minutes to about 120 minutes, preferably between about 45 minutes to about 100 minutes, and more preferably between about 60 minutes to about 80 minutes. In one preferred embodiment, the SSOI structure 31 is annealed at a temperature of at least about 800° C., and more preferably at a temperature of at least about 1000° C., for a duration of at least about 10 minutes, and more preferably at least about 30 minutes.

It is to be noted that the particular construction and configuration of the equipment used to anneal the SSOI structure 31 is not critical in the practice of the present invention. In one particular preferred embodiment, however, the SSOI structure 31 is annealed in a tube annealer.

It is to be further noted that the SSOI structure 31 may optionally be annealed in different atmospheres to provide additional surface improvements. For example, an argon atmosphere may be used in order to diminish oxidation and consumption of the strained silicon layer, while also limiting nitridation damage to the strained silicon layer's surface. Alternatively, a hydrogen atmosphere may be useful to simultaneously restore crystallinity of the strained silicon layer and smooth the surface thereof via surface atom diffusion. Further, an atmosphere comprising hydrogen and HCl gasses may be used to expedite removal of the relaxed layer. In a preferred embodiment, the SSOI structure is annealed in a high nitrogen and low oxygen gas atmosphere. In a more preferred embodiment, the SSOI structure is annealed in a 99% nitrogen and 1% oxygen atmosphere.

The crystallinity and strain of the silicon layer of the SSOI structure after anneal can be measured by using sample preparation and measurements that are generally known in the art. In one preferred embodiment, Raman spectroscopy is used to measure the crystallinity and strain of the silicon layer using means known in the art and as further detailed herein below.

Raman spectroscopy is the collection of light inelastically scattered by a material or compound. When a light of known wavelength strikes a material, the light is shifted according to the chemical functionalities of the material. The intensity of this shifted light depends on both molecular structure and macrostructure. As a result of these phenomena, the collection of the shifted light gives a Raman spectrum that can provide direct information regarding the molecular vibrations of the compound or material. Therefore, in accord with this invention, the SSOI structure is band-fitted with Gaussian-Lorentzian bands to precisely measure the peak positions and the width of the Raman peaks of the strained Si layer of the handle wafer. This can be accomplished with, for example, a Raman microscope using an Ar+ ion beam with a 514.4 nm wavelength at 1 mW.

Without being held to any particular theory, it is generally believed that it is desirable for the crystallinity of strained silicon layer to be as close to that of single crystal silicon as possible, while maintaining the strain therein. Therefore, it has been discovered that the crystallinity of the strained Si layer 14 is improved by annealing the strained silicon on insulator structure 40 as detailed herein, as measured using Raman spectroscopy. In particular, the crystallinity of the strained Si layer after annealing differs from the crystallinity of single crystal silicon by less than about 10%, such as by less than about 9%, by less than about 8%, by less than about 7%, by less than about 6%, and preferably by less than about 5% (e.g., potentially less than about 4%, about 3%, about 2%, or even about 1%). It may be alternatively desirable to express the difference in the crystallinity of strained silicon after annealing and single crystal silicon as a range, such as between about 1% to about 10%, more preferably between about 2% to about 8%, and still more preferably between about 4% to about 6%.

To this end, it is to be noted that this difference is calculated by comparing the Raman spectroscopy scans of the SSOI structure before and after the annealing process. More specifically, “improved crystallinity” as used herein refers to the strained Si layer is changed by the anneal such that when the maximum absorption peak width of the strained Si layer is compared to the maximum absorption peak width of the handle wafer, there is less than about 10% difference therebetween.

It is to be further noted that the strained Si layer and the handle wafer have maximum absorption peaks at different locations, which indicates that the silicon surface layer has undergone strain. The relation between silicon stress for biaxial stress and Raman frequency shift, which is given by Δν=ν_{substrate}−ν_{strained}, is shown by equation (1)
Δν≈−2×10⁻⁹(σₓₓ+σ_{yy}) (1)
where σ is the stress in Pa. The above equation simply means that a down-shift of 1.0 cm⁻¹ corresponds to a tensile stress of 250 MPa if σxx=σyy. The strain in the Si layer is calculated as a percentage by the following formula (2):
ε=0.123 Δν (2)

The strain of the silicon is directly related to the mobility and current drive of transistors built with the SSOI structure. It is therefore desirable that after annealing, the strain in the Si surface layer does not differ significantly from the strain prior to the annealing process. This means that, as determined by Raman spectroscopy, it is desirable for the position of the maximum absorption peak of the strained silicon layer to remain substantially unchanged.

In accordance with the process of the present invention, it has therefore been discovered that the strain in the strained Si layer remains substantially unchanged after being subjected to the annealing temperatures and durations disclosed herein. Stated another way, it has been discovered that the process of the present invention improves the crystallinity of the strained Si layer without causing any measurable relaxation of the strained Si layer. In particular, the position of the maximum absorption peak of the strained Si layer after annealing differs from the position of the maximum absorption peak prior to annealing by less than 1.5 wave numbers, as measured by Raman spectroscopy. For example, the peak position after the anneal differs from the peak position before the anneal by less than 1.4, preferably by less than 1.3, more preferably by less than 1.2, still more preferably by less than 1.1, still more preferably by less than 1.0, still more preferably by less than 0.9, still more preferably by less than 0.8, still more preferably by less than 0.7, still more preferably by less than still 0.6, and even more preferably by less than 0.5 wave numbers.

In this regard it is to be noted that standard Raman spectroscopy equipment currently has an accuracy of within about 0.1 wave numbers.

In view of the foregoing, it is to be noted that the process of the present invention yields a SSOI structure wherein the crystallinity is improved in the strained layer and wherein the strain in the strained surface layer is maximized. Generally, the strain is as high as possible, so long as other properties, such as the strained layer thickness, surface roughness, and defect density, can be maintained. For example, the resulting SSOI structure of the present invention has a level of strain therein of at least about 0.5%, such as at least about 0.6%, at least about 0.7%, or at least about 0.8%. Preferably, the strain level of at least about 0.9%, and even more preferably at least about 1%, with higher levels achievable under improved donor wafer structure 10 preparation techniques.

Although the process of preparing a SSOI structure of the present invention includes annealing the structure after removing the SiGe layer therefrom, it is to be noted that annealing may be integrated into the process in other ways without departing from the scope of the present invention. For example, the annealing step may be performed on the handle wafer prior to removal of the residual relaxed layer, which may optionally be present after layer transfer. Furthermore, a conventional process for producing a SSOI structure may be modified in accordance with the present invention by additionally subjecting the final SSOI structure to a high temperature thermal anneal process as described by the present invention.

3. Strained Silicon on Insulator Structure

The SSOI structure prepared in accordance with the present invention has an improved crystallinity in the strained Si layer while maintaining the beneficial properties of the strained Si layer. For example, the SSOI structure preferably has a strained layer which has a crystallinity that differs from the crystallinity of the single crystal silicon handle wafer by less than about 10%, and preferably by less than about 9%, by less than about 8%, by less than about 7%, by less than about 6%, or even by less than about 5% (e.g., less than about 4%, 3%, 2%, or even 1%). In addition, the SSOI structure may optionally have a strain value of at least about 0.5%, and preferably as least about 0.6%, about 0.7%, about 0.8%, about 0.9%, or even about 1%.

In one preferred embodiment, the SSOI structure has a strained layer which has a crystallinity that differs from the crystallinity of the single crystal silicon handle wafer by less than about 8% and has a strain value of at least about 0.6%. More preferably, the SSOI structure has a strained layer which has a crystallinity that differs from the crystallinity of the single crystal silicon handle wafer by less than about 6% and has a strain value of at least about 0.7%. Still more preferably, the SSOI structure has a strained layer which has a crystallinity that differs from the crystallinity of the single crystal silicon handle wafer by less than about 5% and has a strain value of at least about 0.8%.

Additionally, in these or other embodiments, the strained Si layer may have a substantially uniform thickness ranging from about 1 nm to about 100 nm thick. Preferably, in these or other embodiments, the strained Si layer has a thickness ranging from about 10 nm to about 80 nm, and more preferably from about 20 nm to about 60 nm thick.

The SSOI structure produced in accordance with the present invention is suitable for use in various technologies, including for example the broad complementary-metal-oxide-semiconductor (CMOS) technology field.

The following Examples are simply intended to further illustrate and explain the present invention. The invention should not be limited to any of the details provided herein.

### EXAMPLES

### Example 1

A silicon donor wafer structure was prepared according to the invention by depositing a relaxed SiGe layer having an average thickness of about 0.2 μm via a commercial epitaxial deposition process utilizing a Ge-source gas and a Si-source gas. This was followed by applying a layer of silicon having an average thickness of about 80 nm thereon by means of epitaxial growth in an ASM Epislon 1 single wafer reactor. Hydrogen ions were then implanted into the SiGe layer to a depth of approximately 120 nm by an external implant service, Innovion Corporation, to create a separation plane within the relaxed SiGe layer. Next, a silicon handle structure was prepared by growing a layer of SiO₂ 145 nm thick thereon by means of thermal oxidation in a vertical furnace at 850° C. for 120 minutes.

The two structures were bonded together, forming a bond interface between the strained silicon layer and the SiO₂ layer, by means of N₂-plasma activation with an EAG bonder and hydrophilic bonding. Afterward, the bonded structure was subjected to a bond anneal at 300° C. for 60 minutes. Then, the structure was cleaved on a SiGen cleaver to cause separation along the implanted hydrogen ions separation plane. One of the resulting structures comprised the handle wafer, the SiO₂ layer, the strained silicon layer thereon, and a residual relaxed SiGe layer on the strained silicon layer, the residual relaxed layer having a thickness of about 105 nm. This structure was then exposed to NH₄OH:H₂O₂:H₂O etchant having a ratio of 1:2:50 for 240 minutes at about 65° C., while a megasonic treatment of about 1500 W was applied, in order to substantially remove the residual relaxed layer from the surface of the strained layer.

The resulting 600 Å SSOI thick structure was annealed at 1100° C. in a 99% N₂ and 1% O₂ ambient for 30 minutes. This annealing process was observed to improved the crystallinity of the strained silicon layer, while maintaining the strain therein. More specifically, the crystallinity and the strain of the strained silicon layer was evaluated using Raman spectroscopy. The maximum absorption peak of the strained layer was observed at a position of 515.8 wave numbers, while the maximum absorption peak of the single crystal silicon handle wafer was observed at a position of 520.7 wave numbers. The crystallinity of the strained silicon layer after anneal was determined to differ from the crystallinity of the handle wafer by less than about 6.5%, while the tensile strain of the strained silicon layer is 0.7%. Additionally, with respect to strain, it was determined that little relaxation occurred in the strained layer, as the maximum absorption peak of the strained layer did not shift by any detectable amount of wave numbers after the anneal.

### Example 2

A 600 Å SSOI structure was annealed at a temperature of about 1000° C. for about 30 minutes in an atmosphere substantially comprising nitrogen. More particularly, this anneal began in a mix of about 98% N₂ and about 2% O₂ at 800° C. The temperature was then ramped to about 1000° C. at about 5° C./min and held at the anneal temperature for about 5 min in the same atmosphere. Further, the SSOI structure was annealed for about 25 min in an atmosphere comprising about 100% N₂, then cooled to about 800° C. in this atmosphere at about 3° C./min before being removed from the annealing furnace.

This annealing process was observed to improve the crystallinity of the strained silicon layer, while maintaining the strain therein. More specifically, the crystallinity and the strain of the strained silicon layer were evaluated using Raman spectroscopy. The maximum absorption peak of the strained layer was observed at a position of 515.0 wave numbers, while the maximum absorption peak of the single crystal silicon handle wafer was observed at a position of 520.8 wave numbers. The crystallinity of the strained silicon layer after anneal was determined to differ from the crystallinity of the handle wafer by less than about 7.3%, while the tensile strain of the strained silicon layer is 0.7%. Additionally, with respect to strain, it was determined that little relaxation occurred in the strained layer.

The above description of the preferred embodiments is intended only to acquaint others skilled in the art with the invention, its principles, and its practical application, so that others skilled in the art may adapt and apply the invention in its numerous forms, as may be best suited to the requirements of a particular use. The present invention, therefore, is not limited to the above embodiments, and may be variously modified.

With reference to the use of the word(s) “comprise” or “comprises” or “comprising” in this entire specification (including the claims below), it is noted that unless the context requires otherwise, those words are used on the basis and clear understanding that they are to be interpreted inclusively, rather than exclusively, and that it is intended each of those words to be so interpreted in construing this entire specification (including the claims).

What is claimed is:

1. A process for preparing a strained silicon on insulator structure comprising a handle wafer, a strained silicon layer, and a dielectric layer between the handle wafer and the strained silicon layer, the process comprising annealing the strained silicon on insulator structure at a temperature and for a duration such that the strained silicon layer has a crystallinity which differs from the crystallinity of the handle wafer by less than about 10%.

2. The process of claim 1 wherein said process further comprises:
forming a relaxed silicon-comprising layer on a surface of a donor wafer;
forming a strained silicon layer on the relaxed silicon-comprising layer;
forming the dielectric layer on a surface of the handle wafer;
bonding the strained silicon layer of the donor wafer to the dielectric layer of the handle wafer to form a bonded wafer, wherein a bond interface is formed between the strained silicon layer and the dielectric layer;
separating the bonded wafer along a separation plane within the relaxed silicon-comprising layer, such that the strained silicon layer on said handle wafer has a residual relaxed silicon-comprising layer on the surface thereof; and,
etching the residual relaxed silicon-comprising layer to substantially remove said layer from the strained silicon layer.

3. The process of claim 1 wherein the strained silicon layer has a thickness of at least about 1 nm.

4. The process of claim 1 wherein the strained silicon layer has a thickness of from about 10 nm to about 80 nm.

5. The process of claim 2, wherein said relaxed silicon-comprising layer comprises SiGe.

6. The process of claim 1 wherein the strained silicon on insulator structure is annealed in a nitriding and oxidizing atmosphere.

7. The process of claim 1 wherein the silicon on insulator structure is annealed at a temperature of at least about 800° C.

8. The process of claim 1 wherein the silicon on insulator structure is annealed at a temperature of from about 1000° C. to about 1175° C.

9. The process of claim 1 wherein the silicon on insulator structure is annealed for at least about 10 minutes.

10. The process of claim 1 wherein the silicon on insulator structure is annealed from about 30 minutes to about 120 minutes.

11. The process of claim 1 wherein the strained silicon layer has a crystallinity which differs from the crystallinity of the handle wafer, after said anneal, by less than about 5%.

12. The process of claim 1 wherein the strained silicon layer, after said anneal, has a strain level of at least about 0.5%.

13. The process of claim 1 wherein the strained silicon layer, after said anneal, has a strain level of at least about 1.0%.

14. The process of claim 1 wherein after said anneal, the strain in said strained silicon layer remains substantially unchanged.

15. The process of claim 1 wherein the strained silicon layer has a maximum absorption peak after said anneal that differs from the maximum absorption peak before said anneal by less than 1.5 wave numbers.

16. The process of claim 1 wherein the strained silicon layer has a maximum absorption peak after said anneal that differs from the maximum absorption peak before said anneal by less than 0.5 wave numbers.

17. The process of claim 1 wherein the handle wafer has a diameter of at least about 200 mm.

18. A strained silicon on insulator structure wherein the structure is formed according to the process of claim 1.

19. A strained silicon on insulator structure comprising a handle wafer, a strained silicon layer, and an oxide layer between the handle wafer and the strained layer, said strained layer having a thickness of at least about 1 nm and a crystallinity that differs from the crystallinity of the handle wafer by less than about 10%.

20. The structure of claim 19 wherein the strained silicon layer has a crystallinity which differs from the crystallinity of the handle wafer by less than about 5%.

21. The structure of claim 19 wherein the strained icon layer has a strain level of at least about 0.5%.

22. The structure of claim 19 wherein the strained icon layer has a strain level of at least about 1.0%.

23. The structure of claim 19 wherein the strained icon layer has a thickness of at least about 10 nm to about nm.

24. The structure of claim 19 wherein the handle wafer a diameter of at least about 200 mm.
